(19) United States
(12) Patent Application Publication
(10) Pub. No.: US 2012/0080656 A1
(43) Pub. Date: Apr. 5, 2012

(54) Graphene oxide memory devices and method of fabricating the same

(75) Inventors: Sung Yool Choi, Daejeon (KR); Jong Yun Kim, Daejeon (KR); Hu Young Jeong, Daejeon (KR)

(73) Assignee: ELECTRONICS AND TELECOMMUNICATIONS RESEARCH INSTITUTE, Daejeon (KR)

(21) Appl. No.: 13/200,644

(22) Filed: Sep. 28, 2011

(30) Foreign Application Priority Data
Sep. 30, 2010 (KR) 10-2010-0095404

(51) Int. Cl. H01L 45/00; H01L 21/8239; B82Y 99/00

(52) U.S. Cl. 257/2; 438/382; 977/734; 257/E45.001; 257/E21.645; 257/E21.004

(57) ABSTRACT

A graphene oxide memory device includes a substrate, a lower electrode disposed on the substrate, an electron channel layer disposed on the lower electrode by using a graphene oxide, and an upper electrode disposed on the electron channel layer.

### CROSS-REFERENCE TO RELATED APPLICATIONS

The present application claims priority to Korean patent application number 10-2010-0095404, filed on Sep. 30, 2010, which is incorporated by reference in its entirety.

### BACKGROUND OF THE INVENTION

The present invention relates to graphene oxide memory devices, and more particularly, to flexible graphene oxide memory devices that can be highly integrated, and methods of fabricating the flexible graphene oxide memory devices.

Memory research was started from silicon-based memories and is now conducted on organic memories. Research on silicon-based memories has reached the fields of non-volatile memories and locally flexible memories.

However, the basic limitation of silicon-based memories has not been overcome. In addition, although the electric characteristics of flexible memories can be maintained in case of a small amount of bending, they cannot be maintained in case of a large amount of deformation.

For this reason, much research is being conducted on organic memories to overcome limitation of silicon-based memories.

Organic memory research has reached the study of non-volatile memories and is now being conducted on flexible memories.

The above-described technology is background art given for understanding of the present invention, and it does not mean that the above-described technology is well known in the related art.

However, organic memories formed on a flexible substrate have limitations such as difficulties in coupling with electrodes, variations of memory material properties, and limitations of electrodes.

In addition, current flexible organic memories have limitations such as high operation voltage and slow response time.

That is, flexible organic memories having desired characteristics have not been developed.

Therefore, it is necessary to develop improved flexible organic memory devices.

### SUMMARY OF THE INVENTION

Embodiments of the present invention are directed to graphene oxide memory devices having electrical bistability obtained by forming charge traps between a graphene oxide thin film and an upper electrode by chemical reaction.

In one embodiment, a graphene oxide memory device includes: a substrate; a lower electrode disposed on the substrate; an electron channel layer disposed on the lower electrode by using a graphene oxide; and an upper electrode disposed on the electron channel layer.

The substrate may be formed of one of silicon coated with an insulating layer, PES (polyethersulfone), PET (polyethylene Terephthalate), PC (polycarbonate), and PI (polyimide).

A glue layer or a monomolecular layer may be disposed between the substrate and the lower electrode by a surface treatment.

In another embodiment, there is provided a method of fabricating a graphene oxide memory device, the method including: forming a lower electrode on a substrate; forming an electron channel layer on the lower electrode by using a graphene oxide; and forming an upper electrode on the electron channel layer.

A glue layer or a monomolecular layer may be formed between the substrate and the lower electrode by a surface treatment.

The substrate may be formed of one of silicon coated with an insulating layer, PES, PET, PC, and PI.

The forming of the electron channel layer may be performed by depositing a graphene oxide by using a solution in which graphite is dispersed.

The electron channel layer may be one to ten thousand times wider than the upper electrode or the lower electrode.

The graphene oxide may include an epoxide functional group, an alchol functional group, a hydroxyl functional group, or a carboxyl functional group, so as to be dispersed in a solution or water-soluble solvent in a form of a monomolecular layer.

A dispersion solution prepared by dispersing the graphene oxide into the water-soluble solvent may include approximately 0.01 wt % to approximately 5 wt % of the graphene oxide.

### BRIEF DESCRIPTION OF THE DRAWINGS

The patent or application file contains at least one sheet of drawings executed in color. Copies of this patent or patent application publication with color drawings will be provided by the Office upon request and payment of the necessary fee.

FIG. 1 illustrates a schematic view of a graphene oxide memory device according to a first embodiment of the present invention.

FIG. 2 illustrates current-voltage characteristics of the graphene oxide memory device according to the first embodiment of the present invention.

FIG. 3 illustrates log current-log voltage curves measured by applying a negative voltage according to the first embodiment of the present invention.

FIG. 4 illustrates log current-log voltage curves measured by applying a positive voltage according to the first embodiment of the present invention.

FIG. 5 illustrates a schematic view of a graphene oxide memory device according to a second embodiment of the present invention.

FIG. 6 illustrates current-voltage characteristics of the graphene oxide memory device before and after the graphene oxide memory device is bent, according to the second embodiment of the present invention.

FIG. 7 illustrates results of an Ion/Ioff repeatability test performed on the graphene oxide memory device according to the second embodiment of the present invention.

FIG. 8 illustrates results of an Ion state and Ioff state retention test performed on the graphene oxide memory device according to the second embodiment of the present invention.

FIG. 9 illustrates an image of a graphene oxide memory device captured after bending the graphene oxide memory device, according to a third embodiment of the present invention.

FIG. 10 illustrates current-voltage characteristics of an AL/GO/AL/PES device measured while increasing the number of bending cycles, according to the third embodiment of the present invention.

FIG. 11 illustrates values of currents Ion and Ioff at a reading voltage of approximately −0.5 V with respect to the number of bending cycles according to the third embodiment of the present invention.

FIG. 12 illustrates a schematic view of the AL/GO/AL/PES device and a measurement point of current-voltage characteristics, according to the third embodiment of the present invention.

FIG. 13 illustrates current-voltage characteristics for different amounts of bending, according to the third embodiment of the present invention.

FIG. 14 illustrates values of currents Ion and Ioff at a reading voltage of approximately −0.5 V with respect to the amount of bending, according to the third embodiment of the present invention.

### DESCRIPTION OF SPECIFIC EMBODIMENTS

Hereinafter, graphene oxide memory devices and methods of fabricating the graphene oxide memory devices will be described in detail with reference to the accompanying drawings. In the drawings, the thicknesses of lines or the sizes of elements may be exaggerated for clarity. Also, the terms used herein are defined according to the functions of the present invention. Thus, the terms may vary depending on user's or operator's intension and usage. That is, the terms used herein must be understood based on the descriptions made herein.

According to an embodiment of the present invention, a graphene oxide memory device includes a substrate, a lower electrode, an electron channel layer, and an upper electrode.

The lower electrode and the upper electrode are arranged to cross each other, and the electron channel layer is disposed between the lower electrode and the upper electrode.

The electron channel layer is formed of a graphene oxide thin film.

The substrate may be an insulating substrate such as a silicon substrate coated with an insulating layer. Alternatively, according to applications, the substrate may be a plastic substrate formed of a material such as polyethersulfone (PES), polyethylene terephthalate (PET), polycarbonate (PC), and polyimide (PI).

The lower electrode may be formed of electrode material such as aluminum (Al), copper (Cu), gold (Au), platinum (Pt), indium tin oxide (ITO), and doped silicon by a method such as evaporation, sputtering, and chemical vapor deposition (CVD).

The electron channel layer may make contact with the lower electrode by coating the electron channel layer on the lower electrode entirely or partially.

It is necessary to improve the contact between the electron channel layer and the lower electrode for exact operation of the graphene oxide memory device of the current embodiment of the present invention. For this, a surface treatment may be necessary to form a glue layer or a monomolecular layer of titanium (Ti) or chromium (Cr) between a metal of the lower electrode and an organic material of the electron channel layer.

The lower electrode may have a width in the range from approximately 1 nm to approximately 100 nm. The lower electrode may include a pad for electric contact with an external part. The lower electrode may be formed into a regular pattern shape by using a pattern-forming method such as photolithography, electron beam lithography, and shadow deposition.

In the current embodiment of the present invention, a thin film is formed as the electron channel layer by depositing a graphene oxide (GO) to a uniform thickness by using a solution in which graphite is dispersed by Hummer's method or modified Hummer's method.

The electron channel layer is one to ten thousand times wider than the upper electrode or the lower electrode.

The graphene oxide includes an epoxide functional group, an alchol functional group, a hydroxyl functional group, or a carboxyl functional group, so as to be dispersed in a solution or water-soluble solvent in the form of a monomolecular layer.

A dispersion solution prepared by dispersing the graphene oxide into the water-soluble solvent has approximately 0.01 wt % to approximately 5 wt % of the graphene oxide. Thus, by oxidation-reduction reaction, charge traps can be formed in a part of the graphene oxide thin film, particularly, an interfacial part of the graphene oxide thin film making contact with the upper electrode. Since conduction mechanism is varied according to the amount of trapped charge, that is, according to the charge trap density, resistance switching can be induced.

The upper electrode is formed of a metal material such as aluminum (Al), titanium (Ti), nickel (Ni), chromium (Cr), silver (Ag), platinum (Pt), and tungsten (W).

Charge traps can be formed by chemical reaction between the material of the upper electrode and the organic material of the electron channel layer. Owing to the charge traps, when a voltage is applied between the upper electrode and the lower electrode, a high resistance state is obtained and a current flow is hindered, and if the number of charge traps or the density of charge traps is sufficiently reduced, a low resistance state is obtained. In this way, resistance can be varied.

Therefore, in the graphene oxide memory device of the present invention, a graphene oxide thin film is formed as the electron channel layer having electrical bistability.

The graphene oxide memory device of the present invention includes the insulating substrate, the lower electrode disposed on the substrate, the electron channel layer disposed on the lower electrode by using a graphene oxide, and the upper electrode disposed on the electron channel layer.

In the graphene oxide memory device of the current embodiment, charge traps can be formed by chemical reaction between the upper electrode and an organic active layer constituting the electron channel layer.

If a voltage is applied between the upper electrode and the lower electrode of the graphene oxide memory device, the number of charge traps or the density of charge traps is varied, and thus a current flowing in the electron channel layer is varied.

In this way, a more stable flexible non-volatile memory device can be provided by using a graphene oxide.

Referring to the following embodiments, graphene oxide memory devices having a metal/organic/metal (MOM) structure were fabricated by forming upper and lower electrodes using aluminum (Al) and forming an organic active layer between the upper and lower electrodes as an electron channel layer, and electric characteristics of the graphene oxide memory devices were observed.

### 1. FIRST EMBODIMENT

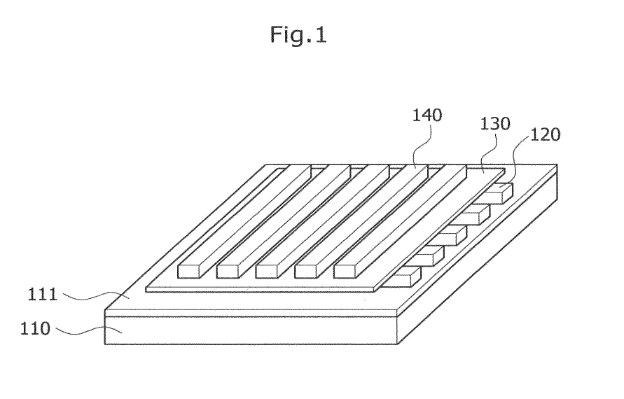

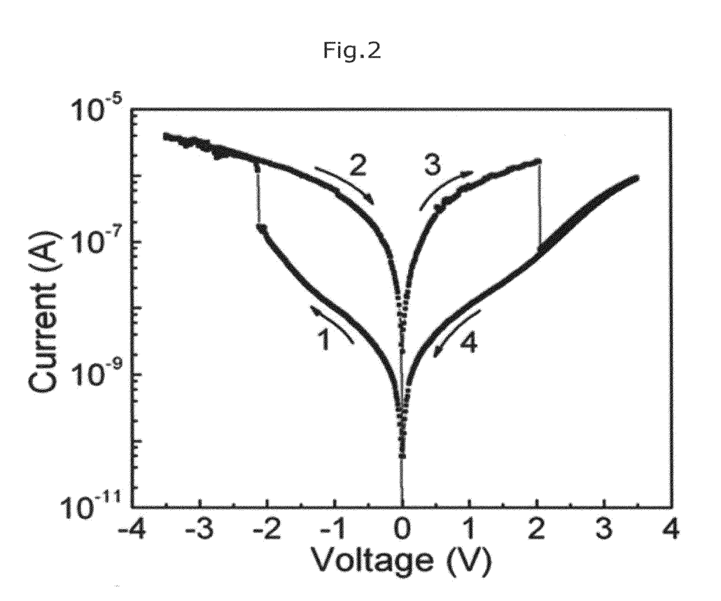

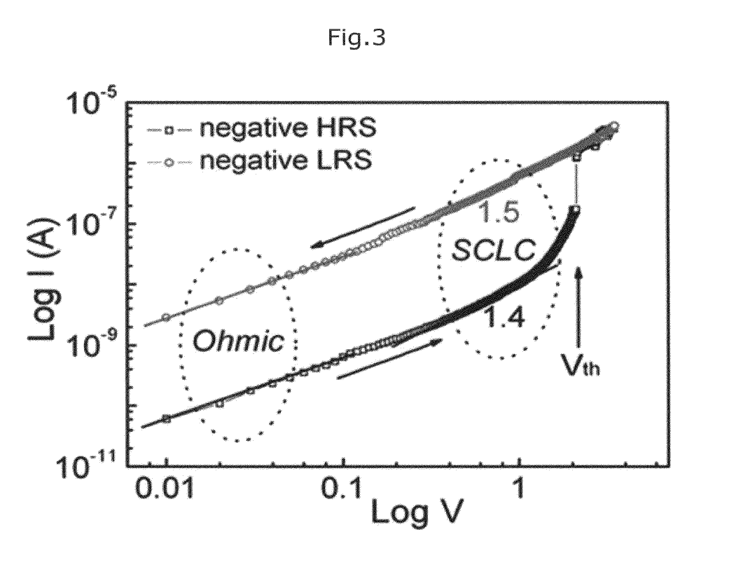

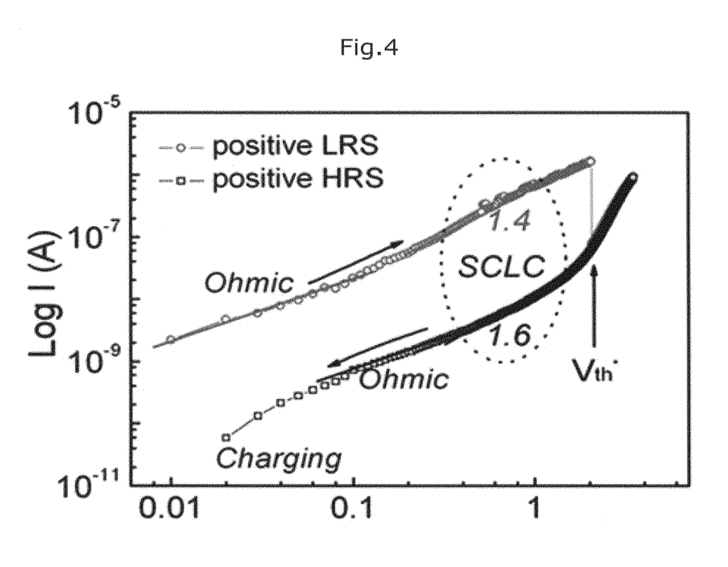

FIG. 1 illustrates a schematic view of a graphene oxide memory device according to a first embodiment of the present invention; FIG. 2 illustrates current-voltage characteristics of the graphene oxide memory device according to the first embodiment of the present invention; FIG. 3 illustrates log current-log voltage curves measured by applying a negative voltage according to the first embodiment of the present invention; and FIG. 4 illustrates log current-log voltage curves measured by applying a positive voltage according to the first embodiment of the present invention.

According to the first embodiment of the present invention, the graphene oxide memory device includes a graphene oxide thin film as an electron channel layer having electrical bistability.

In detail, the graphene oxide memory device of the first embodiment includes a substrate 110 coated with an insulating layer 111, lower electrodes 120 formed on the substrate 110, an electron channel layer 130 formed on the lower electrodes 120 by using a graphene oxide, and upper electrodes 140 formed on the electron channel layer 130.

The substrate 110 is a solid Si (silicon) substrate. The upper electrodes 140 and the lower electrodes 120 are arranged to cross each other.

In the first embodiment of the present invention, the graphene oxide memory device has a bipolar resistance switching (BRS) characteristic owing to space charge limited conduction (SCLC).

In the current-voltage characteristic curves of the graphene oxide memory device shown in FIG. 2, voltage is varied in the directions of arrows.

Electric characteristics of the graphene oxide memory device were measured by applying a voltage in the order of 0 V to −3.5 V (1), −3.5 V to 0 V (2), 0 V to +3.5 V (3), and +3.5V to 0 V (4).

As oxidation occurs, the graphene oxide memory device was switched from a high resistance state to a low resistance state at a threshold voltage Vth of approximately −2.5 V. The graphene oxide memory device was kept in the lower resistance state until a positive threshold voltage Vth*. However, as the voltage was further increased, the graphene oxide memory device was returned to the high resistance state because of a reduction reaction. The graphene oxide memory device was kept in the higher resistance state until the negative threshold voltage Vth.

FIGS. 3 and 4 illustrate log current-log voltage curves measured by applying negative and positive voltages to ascertain the driving mechanism of the graphene oxide memory device.

Referring to the log current-log voltage curves of FIG. 3 measured by applying a negative voltage, in a low voltage range, the graphene oxide memory device showed ohmic current-voltage behavior, and in a high voltage range, the graphene oxide memory device showed SCLC current-voltage behavior until a threshold voltage Vth.

Referring to the log current-log voltage curves of FIG. 4 measured by applying a positive voltage, in a low voltage range, the graphene oxide memory device showed ohmic current-voltage behavior, and in a high voltage range, the graphene oxide memory device showed SCLC current-voltage behavior until the graphene oxide memory device was switched to a high resistance state at a threshold voltage Vth* by reduction reaction. The graphene oxide memory device was kept in the high resistance state until the negative threshold voltage Vth.

### 2. SECOND EMBODIMENT

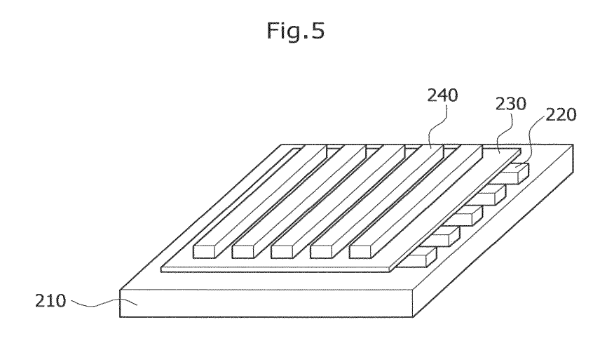

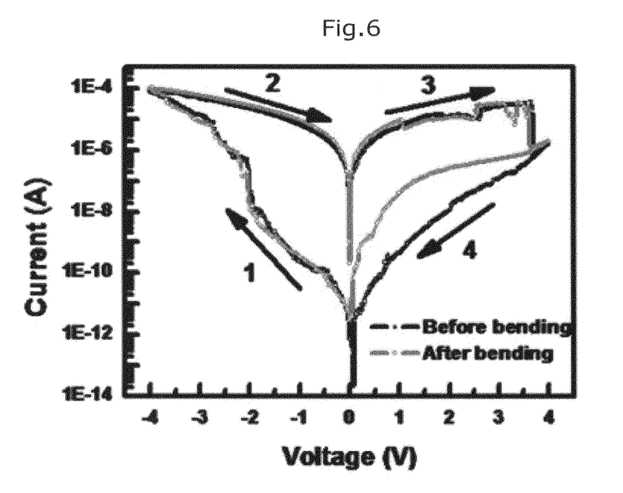

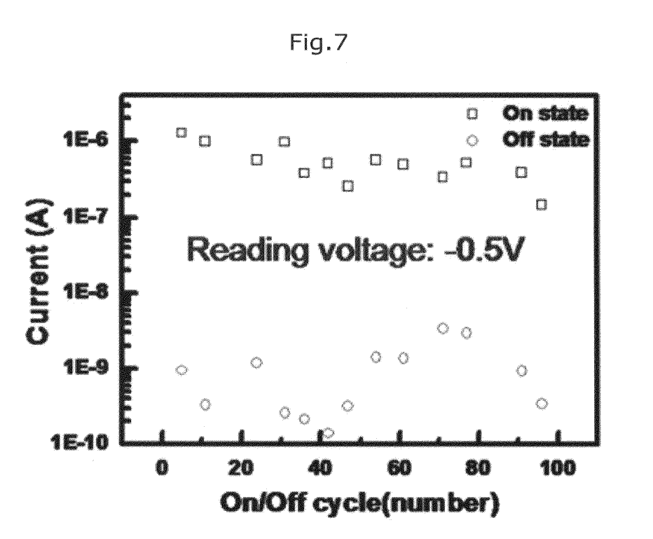

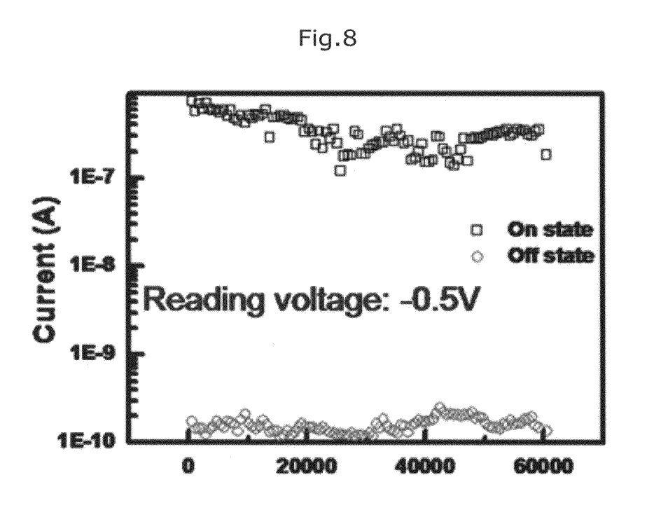

FIG. 5 illustrates a schematic view of a graphene oxide memory device according to a second embodiment of the present invention; FIG. 6 illustrates current-voltage characteristics of the graphene oxide memory device before and after the graphene oxide memory device is bent, according to the second embodiment of the present invention; FIG. 7 illustrates results of an Ion/Ioff repeatability test performed on the graphene oxide memory device according to the second embodiment of the present invention, and FIG. 8 illustrates results of an Ion state and Ioff state retention test performed on the graphene oxide memory device according to the second embodiment of the present invention.

As shown in FIG. 5, the graphene oxide memory device of the second embodiment includes an insulating substrate 210, lower electrodes 220 formed on the substrate 210, an electron channel layer 230 formed on the lower electrodes 220 by using a graphene oxide thin film, and upper electrodes 240 formed on the electron channel layer 230.

The substrate 210 is a flexible PES substrate.

The graphene oxide memory device of the second embodiment of the present invention has the same current-voltage characteristics as the electric characteristics of a conventional oxide memory device.

In FIG. 6 illustrating the characteristic curves of the graphene oxide memory before and after bending, the black curve denotes the characteristics of the graphene oxide memory device before bending and the red curve denotes the characteristics of the graphene oxide memory device after bending. The current-voltage characteristics of the graphene oxide memory device were almost not changed before and after bending.

In the Ion/Ioff repeatability test shown in FIG. 7, a reading voltage was approximately −0.5 V.

The Ion/Ioff repeatability of the graphene oxide memory device was varied as the number of On/Off cycles increases. That is, the Ion/Ioff ratio was slightly reduced. However, the Ion/Ioff ratio was kept approximately 10² or greater.

Referring to FIG. 8, retention at Ion and Ioff states was measured at a reading voltage of approximately −0.5 V. According to the retention test performed on the graphene oxide memory device, the Ioff state was kept almost constant regardless of time. However, the Ion state was slightly degraded with time. However, according to the measured electric characteristics of the graphene oxide memory device, it was determined that the graphene oxide memory device operated stably.

### 3. THIRD EMBODIMENT

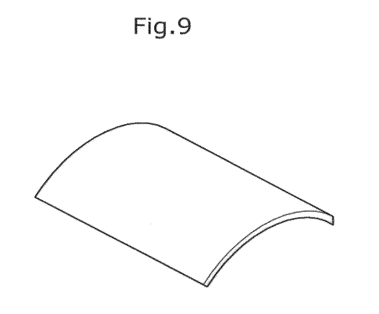

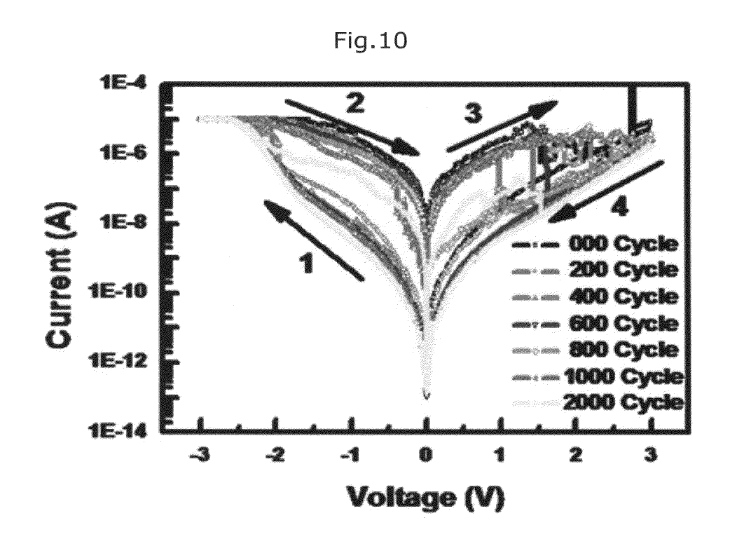

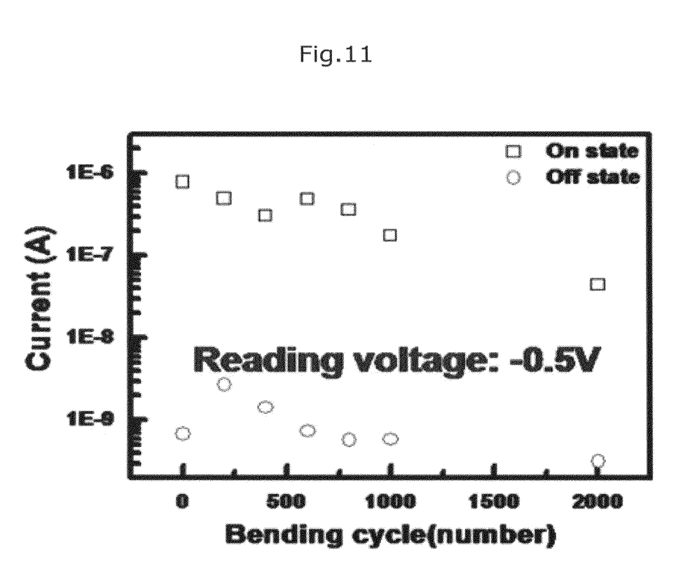

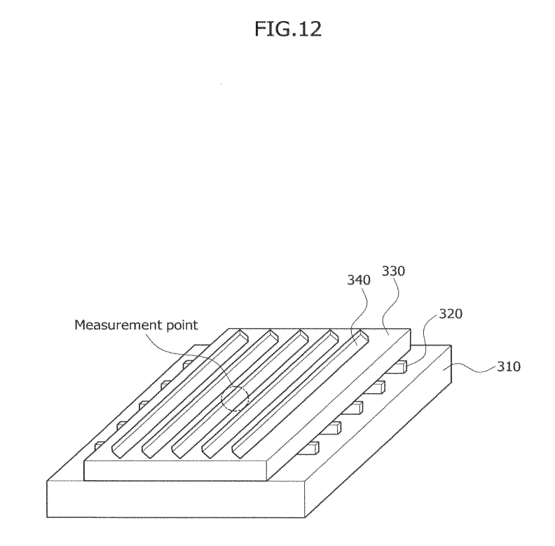

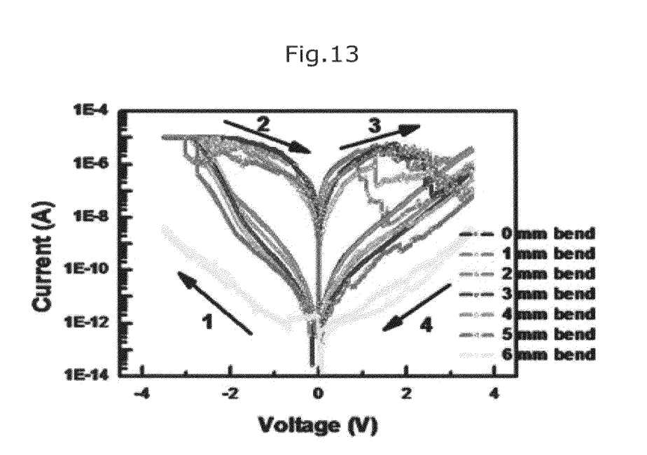

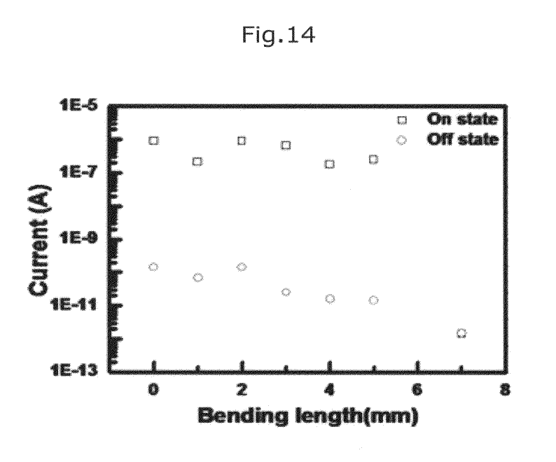

FIG. 9 illustrates an image of a graphene oxide memory device captured after bending the graphene oxide memory device, according to a third embodiment of the present invention; FIG. 10 illustrates current-voltage characteristics of the graphene oxide memory device (AL/GO/AL/PES device) measured while increasing the number of bending cycles, according to the third embodiment of the present invention; FIG. 11 illustrates values of currents Ion and Ioff at a reading voltage of approximately −0.5 V with respect to the number of bending cycles according to the third embodiment of the present invention; FIG. 12 illustrates a schematic view of the AL/GO/AL/PES device and a measurement point of current-voltage characteristics, according to the third embodiment of the present invention; FIG. 13 illustrates current-voltage characteristics for different amounts of bending, according to the third embodiment of the present invention; and FIG. 14 illustrates values of currents Ion/Ioff at a reading voltage of approximately −0.5 V with respect to the amount of bending, according to the third embodiment of the present invention.

As shown in FIG. 12, the graphene oxide memory device of the third embodiment includes an insulating substrate 310, lower electrodes 320 formed on the substrate 310, an electron channel layer 330 formed on the lower electrodes 320 by using a graphene oxide, and upper electrodes 340 formed on the electron channel layer 330.

The substrate 310 is a flexible PES substrate.

According to the third embodiment of the present invention, electric characteristics of the graphene oxide memory device formed on the PES substrate were measured according to the amount of bending and the number of bending cycles.

Although physical characteristics of the graphene oxide memory device of the third embodiment were varied due to repeated bending, the electric characteristics of the graphene oxide memory device were little varied. FIG. 9 illustrates the bending degree of the graphene oxide memory device.

FIG. 10 illustrates current-voltage characteristics of the graphene oxide memory device measured while increasing the number of bending cycles. When the graphene oxide memory device was bent one thousand times or more, the current Ion of the graphene oxide memory device was slightly reduced. However, the Ion/Ioff ratio was maintained.

FIG. 11 illustrates current values (denoted by dots) measured at a reading voltage of −0.5 V with respect to the number of bending cycles. Although the Ion/Ioff ratio was slightly varied, the Ion/Ioff ratio was maintained approximately 10² or greater.

That is, although the substrate 310 is formed of PES, the graphene oxide memory device formed on the substrate 310 by using Al/GO/Al has stable electric characteristics.

FIG. 12 illustrates the measurement point on the graphene oxide memory device. The measurement point is a point of the graphene oxide memory device which is most deformed when the graphene oxide memory device is bent.

The bending test was performed on a 20 mm×20 mm unit device sample while bending the device in increments of 1 mm.

FIG. 13 illustrates current-voltage characteristics for different amounts of bending. That is, the current-voltage characteristics were measured while physically deforming the graphene oxide memory device in the range from approximately 0% to approximately 30%. Although the electric characteristics of the graphene oxide memory device were measured at a point which was most deformed (25%, 5 mm/20 mm), the graphene oxide memory device was stably operated.

The current-voltage characteristics of the graphene oxide memory device were not varied in spite of approximately 25% of physical deformation; however, the graphene oxide memory device did not exhibit memory characteristics in case of approximately 30% of physical deformation.

FIG. 15 illustrates measured current-voltage characteristics according to the amount of bending. Specifically, FIG. 15 illustrates current values measured at a reading voltage of −0.5 V. The current Ioff was gradually reduced as the amount of bending was increased. The current Ion was constant until approximately 25% of physical deformation. However, in case of approximately 30% of physical deformation, the current Ion became equal to the current Ioff.

Therefore, it is considered that the resistance limit of the graphene oxide memory device against physical deformation is approximately 25%.

According to the present invention, the memory device can be switched between a high conductive state and a low conductive state according to an external voltage applied to the memory device, and although the size of devices is reduced, non-uniformity between the devices can be prevented by using uniform nanoparticles. Therefore, memory devices having good characteristics can be provided.

In addition, since a uniform graphene oxide thin film is used instead of an organic material/metal nanoparticle layer/organic material structure, non-uniformity can be prevented between devices although the size of the devices is reduced.

While the present invention has been described with respect to the specific embodiments, it will be apparent to those skilled in the art that various changes and modifications may be made without departing from the spirit and scope of the invention as defined in the following claims.

What is claimed is:

1. A graphene oxide memory device comprising:
a lower electrode disposed on a substrate;
an electron channel layer disposed on the lower electrode by using a graphene oxide; and
an upper electrode disposed on the electron channel layer.

2. The graphene oxide memory device of claim 1, wherein the substrate is formed of one of silicon coated with an insulating layer, PES (polyethersulfone), PET (polyethylene Terephthalate), PC (polycarbonate), and PI (polyimide).

3. The graphene oxide memory device of claim 2, wherein a glue layer or a monomolecular layer is disposed between the substrate and the lower electrode by a surface treatment.

4. A method of fabricating a graphene oxide memory device, the method comprising:
forming a lower electrode on a substrate;
forming an electron channel layer on the lower electrode by using a graphene oxide; and
forming an upper electrode on the electron channel layer.

5. The method of claim 4, wherein a glue layer or a monomolecular layer is formed between the substrate and the lower electrode by a surface treatment.

6. The method of claim 4, wherein the substrate is formed of one of silicon coated with an insulating layer, PES, PET, PC, and PI.

7. The method of claim 4, wherein the forming of the electron channel layer is performed by depositing a graphene oxide by using a solution in which graphite is dispersed.

8. The method of claim 4, wherein the electron channel layer is one to ten thousand times wider than the upper electrode or the lower electrode.

9. The method of claim 7, wherein the graphene oxide comprises an epoxide functional group, an alchol functional group, a hydroxyl functional group, or a carboxyl functional group, so as to be dispersed in a solution or water-soluble solvent in a form of a monomolecular layer.

10. The method of claim 9, wherein a dispersion solution prepared by dispersing the graphene oxide into the water-soluble solvent comprises approximately 0.01 wt % to approximately 5 wt % of the graphene oxide.
